(19) United States
(12) Patent Application Publication
(10) Pub. No.: US 2012/0188729 A1
(43) Pub. Date: Jul. 26, 2012

(54) PRINTED CIRCUIT BOARD AND MANUFACTURING METHOD THEREOF

(75) Inventor: Toshihiko NAKANO, Tokyo (JP)

(73) Assignee: NEC Corporation, Tokyo (JP)

(21) Appl. No.: 13/355,008

(22) Filed: Jan. 20, 2012

(30) Foreign Application Priority Data
Jan. 24, 2011 (JP) 2011-011882

(51) Int. Cl. H05K 1/00; H05K 3/10

(52) U.S. Cl. 361/748; 29/846

(57) ABSTRACT

A printed circuit board (PCB) according to an exemplary aspect of the present invention includes a plate-like member, a power supply circuit, a power supply line, and a ground line. The plate-like member has a surface on which a semiconductor device is mounted. The power supply circuit is embedded in the plate-like member in a region in which the semiconductor device is mounted, and outputs a power supply voltage and a ground voltage. The power supply line is formed in the plate-like member between the semiconductor device and the power supply circuit, and supplies the power supply voltage output from the power supply circuit to the semiconductor device. The ground line is formed in the plate-like member between the semiconductor device and the power supply circuit, and supplies the ground voltage output from the power supply circuit to the semiconductor device.

### INCORPORATION BY REFERENCE

This application is based upon and claims the benefit of priority from Japanese patent application No. 2011-11882, filed on Jan. 24, 2011, the disclosure of which is incorporated herein in its entirety by reference.

### BACKGROUND OF THE INVENTION

1. Technical Field

The present invention relates to a printed circuit board (PCB) and a manufacturing method thereof, and more particularly, to a PCB that suppresses noise in power supplied to a mounted semiconductor device, and a manufacturing method thereof.

2. Background Art

There is a growing demand for a highly functional LSI in a system. In order to meet this demand, measures have been taken to increase clock speeds in each LSI. Since then, it has become difficult to further increase clock speeds due to limitations of semiconductor processes. For this reason, multi-core technology has been increasingly used as a method for improving the performance of each LSI. In the multi-core technology, multiple processor cores are mounted on a single LSI. The mounted multiple processor cores are caused to execute parallel processing, thereby improving the performance of the entire LSI.

The use of such a technology for improving the performance of the LSI increases power consumption in the LSI. Accordingly, fluctuation in potential of a power supply line and a ground line (PDN: Power Distribution Network) during operation, that is, so-called power supply noise, has become a problem. In particular, the number of transistors provided in the LSI to which the multi-core technology is applied increases compared to a normal LSI, with the result that the problem becomes obvious. Additionally, in the LSI to which the multi-core technology is applied, a technology for dynamically reducing the frequency of each processor core or changing a power supply voltage is used to suppress power consumption and temperature rise. Such a technology also causes an increase in power supply noise. It is important to take a countermeasure against power supply noise, because an operation failure occurs when the power supply noise increases.

As an example of a power supply unit for supplying power to an LSI, a thin power supply unit that achieves a reduction in mounting area is proposed (e.g., see Japanese Unexamined Patent Application Publication No. 2004-289912). Additionally, a configuration is proposed in which a semiconductor IC chip (LSI) is embedded in a multilayer wiring substrate including a DC power supply circuit and the multilayer wiring substrate is mounted on a printed circuit board to thereby suppress the mounting area (Japanese Unexamined Patent Application Publication No. 2008-53319).

### SUMMARY

However, the present inventor has found a problem as described below. Power supply noise is determined depending on an impedance of the PDN when a power supply circuit that supplies a current is viewed from an LSI that consumes the current, and on a displacement current of the LSI. Assuming that a change in current of the LSI is represented by ΔI and an impedance of the PDN is represented by Z, a power supply noise amount ΔV can be expressed by the following equation.

ΔV=ΔI×Z

Because the impedance of the PDN has frequency characteristics, it is basically necessary to set the impedance of the PDN to be equal to or smaller than an allowable value in all frequency bands. This allowable value is referred to as a target impedance of a system in which an LSI is mounted.

In many cases, a typical power supply circuit is disposed to be apart from the LSI, whose power consumption is to be reduced, on a printed circuit board (PCB). In this case, the power supply circuit and the LSI are connected to each other by a wiring layer dedicated to power supply. Similarly, aground voltage (GND potential) is also connected by a dedicated wiring layer. A PDN between the power supply circuit and the LSI has an impedance including R (parasitic resistance), L (parasitic inductance), and C (parasitic capacitance). These impedance characteristics vary depending on frequencies. Typically, when the parasitic inductance is large, the impedance in a high frequency band increases. When the impedance is large, a potential drop caused by a current increases. This potential drop becomes power supply noise. As the distance between the power supply circuit and the LSI increases, the parasitic inductance between the power supply circuit and the LSI increases, resulting in an increase in power supply noise.

When two or more types of powers are supplied to the LSI, it is necessary to design a layout by increasing the number of planes or dividing one plane. In the case of increasing the number of planes, however, the number of layers of the printed circuit board is increased. This causes a problem of an increase in manufacturing cost. Furthermore, via holes for connecting planes in a lower layer increase in length, which causes a problem of an increase in the number of parasitic inductances.

FIG. 5 is a layout diagram showing a substantial part of a printed circuit board 600 when one layer is divided into a plurality of power supply planes. As shown in FIG. 5, four power supply planes 61 to 64 are formed on a substrate 60 in the printed circuit board 600. An LSI case 65 is mounted so as to be positioned on the power supply planes 61 to 64. In the printed circuit board 600, the areas of the power supply planes 61 to 64 are reduced, which causes a problem of an increase in parasitic inductance.

As a countermeasure against this problem, there is a method for mounting a voltage regulator circuit in the LSI. This method can solve the above-mentioned problem, but has another problem in that the cost of the LSI considerably increases due to an increase in the size of the LSI because of the voltage regulator circuit mounted thereon. Further, the voltage regulator circuit requires no functionally advanced semiconductor process, but should be formed using semiconductor processes so that the voltage regulator circuit can be mounted on the LSI. This adversely affects the production yield of the entire LSI, and this leads to a further increase in cost. Furthermore, when various types of power supplies are required, it is necessary to mount a plurality of voltage regulator circuits, which leads to a further increase in cost.

The thin power supply unit and DC power supply circuit described above are intended to suppress the mounting area, and thus are insufficient to suppress the power supply noise.

The present invention has been made in view of the above-mentioned circumstances, and therefore has an object to provide a printed circuit board (PCB) capable of suppressing power supply noise generated due to a PDN between a power supply circuit and a semiconductor device, and a manufacturing method thereof.

In a first exemplary aspect of the invention, a printed circuit board (PCB) includes: at least one plate-like member having a surface on which a semiconductor device is mounted; at least one power supply circuit that outputs a power supply voltage and aground voltage, the power supply circuit being embedded in the plate-like member in a region in which the semiconductor device is mounted; a power supply line that supplies the power supply voltage output from the power supply circuit to the semiconductor device, the power supply line being formed in the plate-like member between the semiconductor device and the power supply circuit; and aground line that supplies the ground voltage output from the power supply circuit to the semiconductor device, the ground line being formed in the plate-like member between the semiconductor device and the power supply circuit.

In a second exemplary aspect of the invention, a method of manufacturing a printed circuit board (PCB) includes: forming a power supply circuit that outputs a power supply voltage and aground voltage, the power supply circuit being embedded in a plate-like member in a region in which a semiconductor device is mounted; forming a power supply line that supplies the power supply voltage output from the power supply circuit to the semiconductor device, in the plate-like member between the semiconductor device and the power supply circuit; and forming a ground line that supplies the ground voltage output from the power supply circuit to the semiconductor device, in the plate-like member between the semiconductor device and the power supply circuit.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a sectional view showing a printed circuit board (PCB) 100 according to a first exemplary embodiment on which a semiconductor device is mounted;

FIG. 2 is a layout diagram showing a configuration of a high-voltage DC power supply plane 2 according to the first exemplary embodiment;

FIG. 3 is a sectional view showing a substantial part of a PCB 200 according to a second exemplary embodiment on which a semiconductor device is mounted;

FIG. 4 is a sectional view showing a substantial part of a PCB 300 according to a third exemplary embodiment on which a semiconductor device is mounted; and

FIG. 5 is a layout diagram showing a substantial part of a printed circuit board 600 when one layer is divided into a plurality of power supply planes.

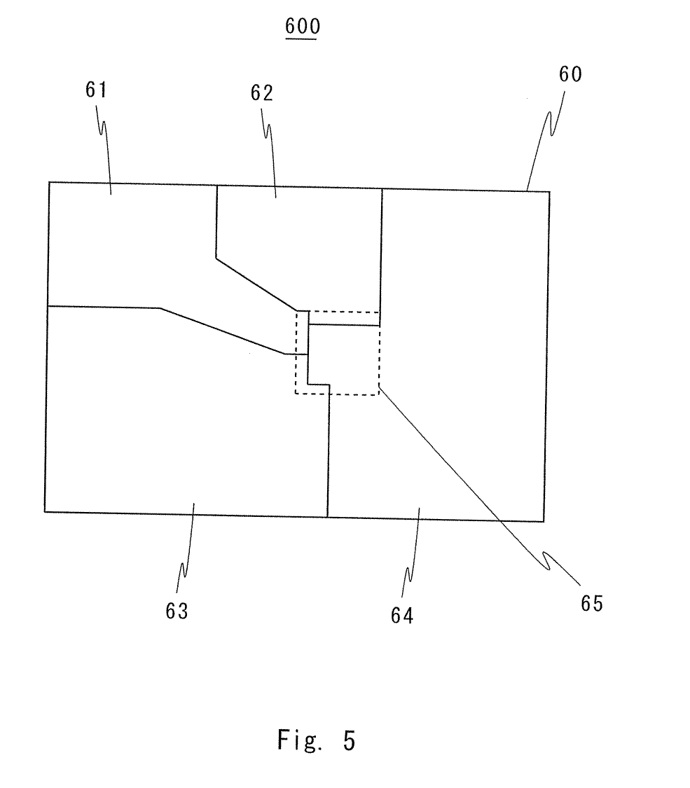

### EXEMPLARY EMBODIMENTS

Hereinafter, exemplary embodiments of the present invention will be described with reference to the accompanying drawings. The same components are denoted by the same reference numerals throughout the drawings, and a redundant explanation thereof is omitted as needed.

### First Exemplary Embodiment

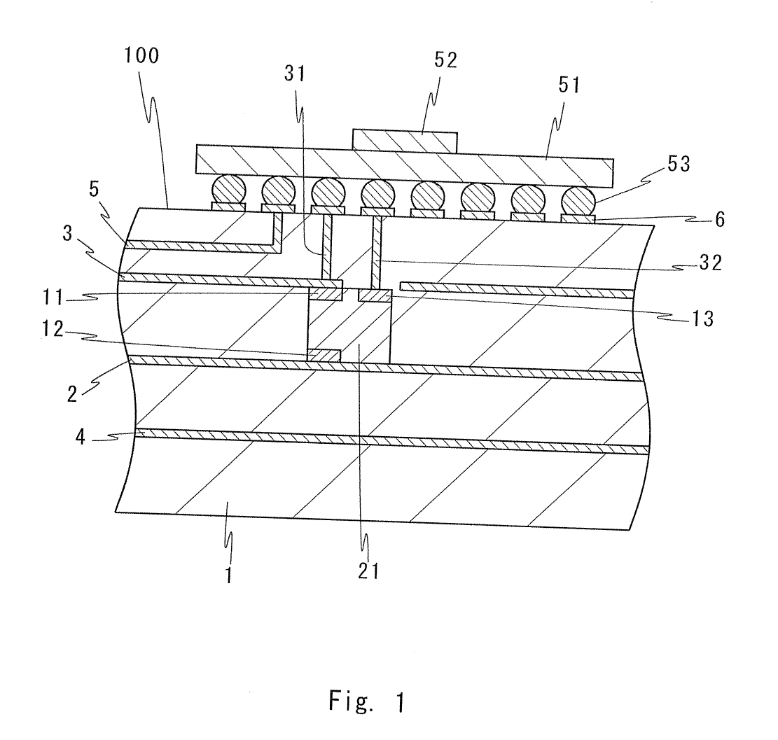

First, a printed circuit board (PCB) 100 according to a first exemplary embodiment of the present invention will be described. FIG. 1 is a sectional view showing a substantial part of the PCB 100 according to the first exemplary embodiment on which a semiconductor device is mounted. The PCB 100 is a printed circuit board, for example. As shown in FIG. 1, an LSI case 51 is mounted on the PCB 100. An LSI 52 is mounted on the LSI case 51. Pins 53 which connect the LSI case 51 with pads 6 are formed on a lower surface of the LSI case 51. The LSI case 51, the LSI 52, and the pins 53 constitute one semiconductor device. A plate-like member 1 extends in the horizontal direction of FIG. 1, but only a part of the plate-like member 1 is shown for simplicity of the drawing.

The PCB 100 includes the plate-like member 1, a high-voltage DC power supply plane 2, ground planes 3 and 4, a signal plane 5, the pads 6, a power supply circuit 21, and via holes 31 and 32. The high-voltage DC power supply plane 2, the ground planes 3 and 4, the signal plane 5, the power supply circuit 21, and the via holes 31 and 32 are formed so as to be embedded in the plate-like member 1.

The power supply circuit 21 includes a ground terminal 11, a high-voltage DC power supply terminal 12, and a power supply terminal 13. The power supply circuit 21 is formed so as to be embedded in the plate-like member 1 between the high-voltage DC power supply plane 2 and the ground plane 3. The ground terminal 11 is connected to the ground plane 3. The high-voltage DC power supply terminal 12 is connected to the high-voltage DC power supply plane 2. The power supply terminal 13 is not connected to the ground plane 3 and independent from the ground plane 3.

The ground terminal 11 and the corresponding pad 6 are connected through the via hole 31 serving as a ground line. The power supply terminal 13 and the corresponding pad 6 are connected through the via hole 32 serving as a power supply line. Accordingly, a DC power supply voltage VDD output from the power supply terminal 13 is supplied to the LSI 52 through the via hole 32, the corresponding pad 6, the corresponding pin 53, and the LSI case 51. A ground voltage GND output from the ground terminal 11 is supplied to the LSI 52 through the via hole 31, the corresponding pad 6, the corresponding pin 53, and the LSI case 51.

In the first exemplary embodiment, only one power supply circuit 21 that is mounted on the plate-like member 1 is shown for simplicity of the drawing. In practice, however, a necessary number of power supply circuits 21 are mounted. In FIG. 1, some of the pins 53 formed on the lower surface of the LSI case 51 are illustrated as being connected to nothing, for simplicity of the drawing. In practice, each pin 53 is connected to another power supply circuit, a signal line extracting part, or the like.

Next, operation of the PCB 100 according to the first exemplary embodiment will be described. The high-voltage DC power supply plane 2 is a plane for supplying a high-voltage DC power supply voltage VDH. The high-voltage DC power supply voltage VDH, which indicates a voltage higher than an operating voltage of the LSI 52, is 12 V or 24 V, for example. The PCB 100 is supplied with the high-voltage DC power supply voltage VDH through the high-voltage DC power supply terminal 12, and outputs the DC power supply voltage VDD obtained by stepping down the high-voltage DC power supply voltage VDH. Since the power supply terminal 13 is connected to the corresponding pin 53 of the LSI case 51, the DC power supply voltage VDD is supplied to the LSI 52 through the LSI case 51. The stepped down DC power supply voltage VDD, which is used in the LSI 52, is 1.8 V or 1.5 V, for example.

According to this configuration, the DC power supply voltage VDD output from the power supply circuit 21 is directly provided to the LSI case 51 through the via hole 32. The ground voltage GND output from the power supply circuit 21 is directly connected to the LSI case 51 through the via hole 31. In other words, the power supply circuit 21 can be disposed immediately below the LSI case 51, so that the power supply circuit 21 and the LSI case 51 can be connected to each other at a shortest distance by a ground line (via hole 31) and a power supply line (via hole 32). Consequently, it is possible to reduce a parasitic inductance which is an important factor for determining an impedance between the power supply circuit 21 and the LSI 52.

Further, when a plurality of power supply circuits 21 are disposed immediately below the LSI case 51, a plurality of individual voltages can be extracted. In this case, different voltages can be extracted depending on the type of I/O, for example. As a result, it becomes possible to let the same PCB cope with changes in specifications of the LSI. According to this configuration, the voltage of a certain I/O can be easily changed from 1.8 V to 1.5 V, for example.

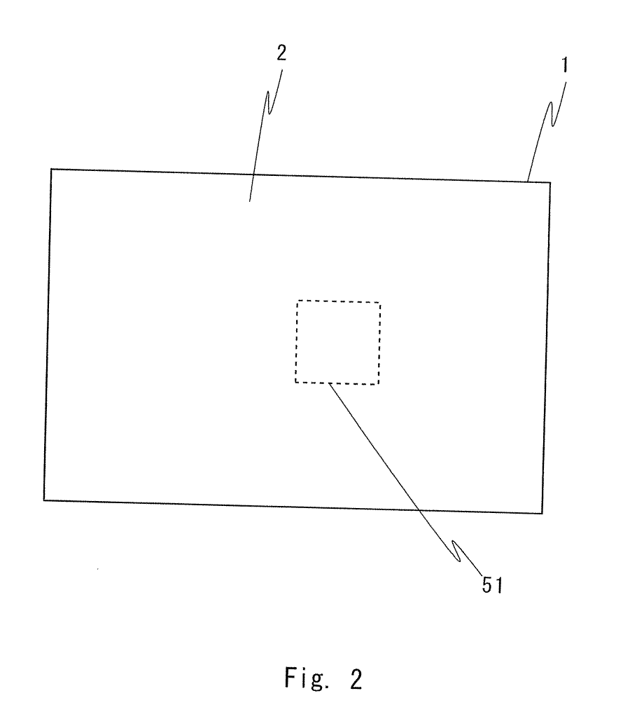

Furthermore, since different voltages can be supplied from the plurality of power supply circuits 21 to the LSI 52, only one high-voltage DC power supply plane 2 needs to be provided. In other words, according to this configuration, there is no need to provide a plurality of high-voltage DC power supply planes. FIG. 2 is a layout diagram showing the configuration of the high-voltage DC power supply plane 2. As shown in FIG. 2, the high-voltage DC power supply plane 2 can be formed over the entire area of the board, for example. Note that in FIG. 2, the position where the LSI case 51 is mounted is indicated by a dashed line. That is, according to this configuration, the number of power supply planes of the printed circuit board can be reduced, which leads to a reduction in cost of the printed circuit board.

In addition, the power supply circuit 21 can be easily formed by existing semiconductor processes. Therefore, the PCB can be formed at low cost, which contributes to a reduction in cost of the entire system.

### Second Exemplary Embodiment

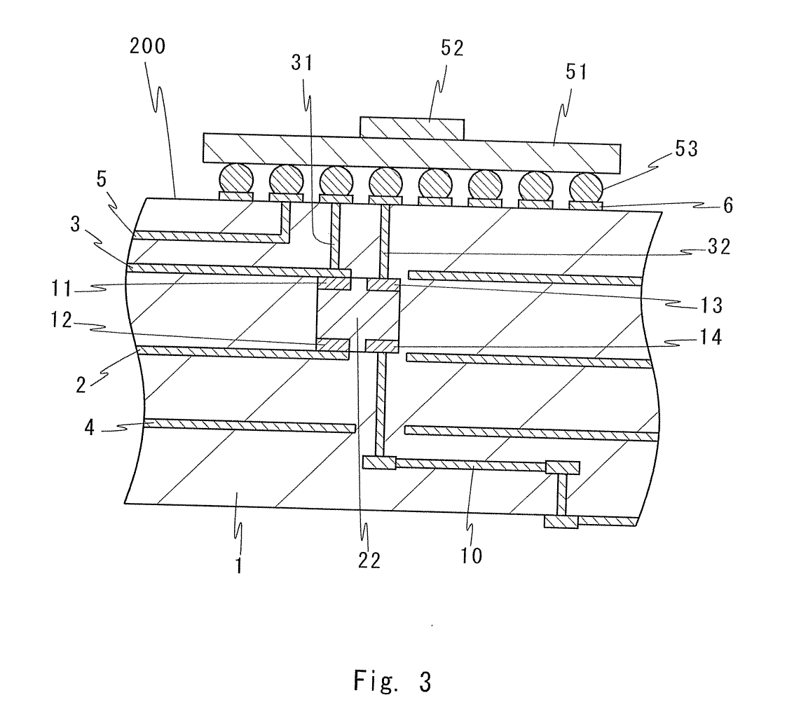

Next, a printed circuit board (PCB) 200 according to a second exemplary embodiment of the present invention will be described. FIG. 3 is a sectional view showing a substantial part of the PCB 200 according to the second exemplary embodiment on which a semiconductor device will be described. As shown in FIG. 3, the PCB 200 has a configuration in which a signal line 10 is added to the PCB 100 according to the first exemplary embodiment. In the PCB 200, a power supply circuit 22 is provided in place of the power supply circuit 21 of the PCB 100. The other components of the PCB 200 are similar to those of the PCB 100, so the description thereof is omitted.

The power supply circuit 22 has a configuration in which a signal terminal 14 is added to the power supply circuit 21. The signal terminal 14 is supplied with a control signal from the outside of the PCB 200 through the signal line 10. The other components of the power supply circuit 22 are similar to those of the power supply circuit 21, so the description thereof is omitted.

Next, operation of the PCB 200 according to the second exemplary embodiment will be described. In the PCB 200, a control signal can be supplied to the power supply circuit 22. Accordingly, the value of the DC power supply voltage VDD output from the power supply terminal 13 can be changed in response to the control signal. Further, the output of the power supply circuit 22 can be disabled (turned off) in response to the control signal. In this configuration, the output of the power supply circuit 22 is disabled (turned off) when no power supply is required, thereby making it possible to reduce power consumption.

According to this configuration, the power supply to a specific area of an LSI in which no power supply is required as a system can be interrupted. Specifically, the power supply to a process core whose operation is not required can be interrupted, for example. Therefore, according to this configuration, it is possible to obtain the operation and effect similar to those of the PCB 100, and it is also possible to reduce the power consumption of the system.

### Third Exemplary Embodiment

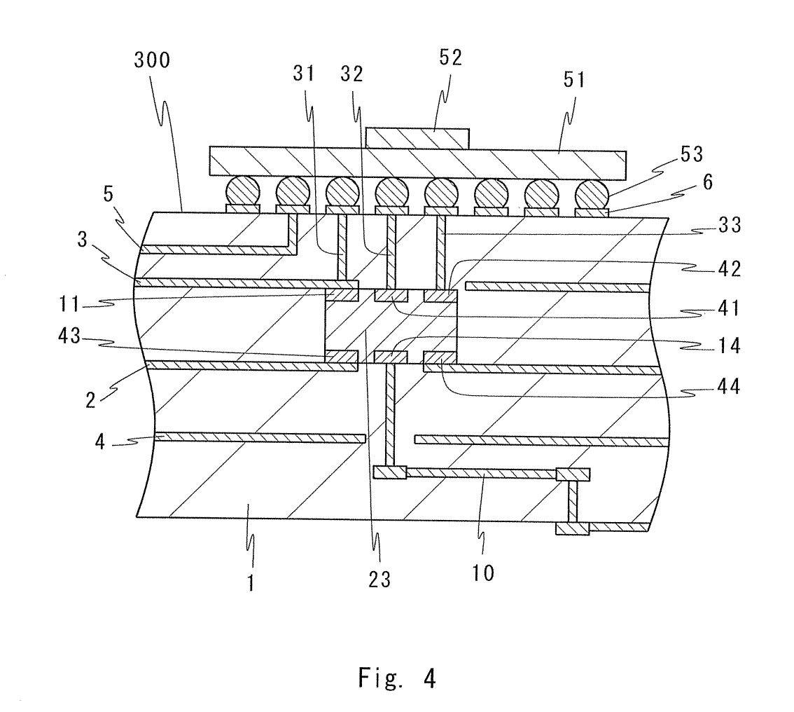

Next, a printed circuit board (PCB) 300 according to a third exemplary embodiment of the present invention will be described. FIG. 4 is a sectional view showing a substantial part of the PCB 300 according to the third exemplary embodiment on which a semiconductor device is mounted. As shown in FIG. 4, the PCB 300 has a configuration in which a power supply circuit 23 is replaced with the power supply circuit 22 of the PCB 200 according to the second exemplary embodiment. The other components of the PCB 300 are similar to those of the PCB 200, so the description thereof is omitted.

The power supply circuit 23 includes a first power supply terminal 41, a second power supply terminal 42, a first high-voltage DC power supply terminal 43, a second high-voltage DC power supply terminal 44, the ground terminal 11, and the signal terminal 14. The first power supply terminal 41 and the second power supply terminal 42 are not connected to the ground plane 3 and independent from the ground plane 3. The first power supply terminal 41 is connected to the LSI 52 through the via hole 32, the corresponding pad 6, the corresponding pin 53, and the LSI case 51. The second power supply terminal 42 is connected to the LSI 52 through a via hole 33, the corresponding pad 6, the corresponding pin 53, and the LSI case 51. The first high-voltage DC power supply terminal 43 and the second high-voltage DC power supply terminal 44 are connected to the high-voltage DC power supply plane 2. The other components of the power supply circuit 23 are similar to those of the power supply circuit 22, so the description thereof is omitted.

Specifically, the power supply circuit 23 can output a plurality of DC power supply voltages. The plurality of DC power supply voltages may be set to different values or the same value. The outputs of the DC power supply voltages can be turned on/off collectively or separately according to a control signal supplied to the signal terminal 14. Furthermore, the voltage values of the DC power supply voltages can be changed collectively or separately according to the control signal supplied to the signal terminal 14.

Therefore, according to this configuration, it is possible to obtain the operation and effect similar to those of the PCB 200, and it is also possible to output a plurality of DC power supply voltages from a single power supply circuit 23. As a result, according to this configuration, the number of power supply circuits can be reduced without impairing the function of the printed circuit board. Moreover, a plurality of DC power supply voltages can be generated based on the high-voltage DC power supply voltage supplied from a single high-voltage DC power supply plane.

Note that the present invention is not limited to the exemplary embodiments described above, but can be modified in various manners without departing from the scope of the present invention. For example, although via holes are formed to connect the power supply circuit and the semiconductor device in the above-mentioned exemplary embodiments, lines other than the via holes may be formed.

While the signal line 10 is provided in the PCB 300 according to the third exemplary embodiment, the signal line 10 may be omitted as in the PCB 100.

The power supply circuits according to the exemplary embodiments described above generate the DC power supply voltage by stepping down the high-voltage DC power supply voltage, but the method of generating the DC power supply voltage is not limited to this. That is, the DC power supply voltage can be generated by transforming the high-voltage DC power supply voltage.

The PCBs according to the exemplary embodiments described above can be applied not only to a system using a semiconductor device and having low power consumption, but also to a system having large power consumption. In particular, the PCBs according to the exemplary embodiments described above can be effectively applied to a mobile terminal, such as a cellular phone, which is inevitably required to achieve low power consumption and low cost.

A part or all of the exemplary embodiments described above can also be expressed as the following supplementary notes, but the present invention is not limited to the supplementary notes described below.

(Supplementary note 1) A printed circuit board (PCB) comprising: a plate-like member having a surface on which a semiconductor device is mounted; at least one power supply circuit that outputs a power supply voltage and aground voltage, the power supply circuit being embedded in the plate-like member in a region in which the semiconductor device is mounted; at least one power supply line that supplies the power supply voltage output from the power supply circuit to the semiconductor device, the power supply line being formed in the plate-like member between the semiconductor device and the power supply circuit; and a ground line that supplies the ground voltage output from the power supply circuit to the semiconductor device, the ground line being formed in the plate-like member between the semiconductor device and the power supply circuit.

(Supplementary note 2) The PCB according to Supplementary note 1, wherein the power supply line and the ground line connect the semiconductor device and the power supply circuit to each other at a shortest distance.

(Supplementary note 3) The PCB according to Supplementary note 1 or 2, wherein the power supply line and the ground line are connected to different electrodes formed on an area opposed to the plate-like member of the semiconductor device, respectively.

(Supplementary note 4) The PCB according to any one of Supplementary notes 1 to 3, further comprising a power supply plane that supplies a voltage to the power supply circuit, the power supply plane being formed in the plate-like member, wherein the power supply circuit transforms the voltage supplied from the power supply plane to generate the power supply voltage.

(Supplementary note 5) The PCB according to Supplementary note 4, wherein the voltage supplied from the power supply plane is higher than the power supply voltage.

(Supplementary note 6) The PCB according to any one of Supplementary notes 1 to 5, further comprising a signal line that supplies a control signal received from an outside of the plate-like member to the power supply circuit.

(Supplementary note 7) The PCB according to Supplementary note 6, wherein the power supply circuit turns on/off an output of the power supply voltage in response to the control signal.

(Supplementary note 8) The PCB according to Supplementary note 6 or 7, wherein the power supply circuit changes a voltage value of the power supply voltage in response to the control signal.

(Supplementary note 9) The PCB according to any one of Supplementary notes 1 to 5, wherein the at least one power supply line comprises a plurality of power supply lines, and
the power supply circuit outputs a plurality of output voltages having different voltage values through a plurality of electric lines, respectively.

(Supplementary note 10) The PCB according to Supplementary note 9, further comprising a signal line that supplies a control signal received from an outside of the plate-like member to the power supply circuit.

(Supplementary note 11) The PCB according to Supplementary note 10, wherein the power supply circuit separately turns on/off outputs of the plurality of power supply voltages in response to the control signal.

(Supplementary note 12) The PCB according to Supplementary note 10 or 11, wherein the power supply circuit separately changes voltage values of the plurality of power supply voltages in response to the control signal.

(Supplementary note 13) The PCB according to any one of Supplementary notes 1 to 12, further comprising a ground plane that supplies the ground voltage to the power supply circuit, the ground plane being formed in the PCB.

(Supplementary note 14) The PCB according to Supplementary notes 1 to 13, wherein the at least one power supply circuit comprises a plurality of power supply circuits.

(Supplementary note 15) A method of manufacturing a printed circuit board (PCB), comprising: forming a power supply circuit that outputs a power supply voltage and a ground voltage, the power supply circuit being embedded in a plate-like member in a region in which a semiconductor device is mounted; forming a power supply line that supplies the power supply voltage output from the power supply circuit to the semiconductor device, in the plate-like member between the semiconductor device and the power supply circuit; and forming a ground line that supplies the ground voltage output from the power supply circuit to the semiconductor device, in the plate-like member between the semiconductor device and the power supply circuit.

According to exemplary embodiments of the present invention, it is possible to provide a PCB capable of reducing noise in power supplied to a mounted semiconductor device, and a manufacturing method thereof.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A printed circuit board (PCB) comprising:
a plate-like member having a surface on which a semiconductor device is mounted;
at least one power supply circuit that outputs a power supply voltage and aground voltage, the power supply circuit being embedded in the plate-like member in a region in which the semiconductor device is mounted;
at least one power supply line that supplies the power supply voltage output from the power supply circuit to the semiconductor device, the power supply line being formed in the plate-like member between the semiconductor device and the power supply circuit; and
a ground line that supplies the ground voltage output from the power supply circuit to the semiconductor device, the ground line being formed in the plate-like member between the semiconductor device and the power supply circuit.

2. The PCB according to claim 1, wherein the power supply line and the ground line connect the semiconductor device and the power supply circuit to each other at a shortest distance.

3. The PCB according to claim 1, wherein the power supply line and the ground line are connected to different electrodes formed on an area opposed to the plate-like member of the semiconductor device, respectively.

4. The PCB according to claim 1, further comprising a power supply plane that supplies a voltage to the power supply circuit, the power supply plane being formed in the plate-like member,
wherein the power supply circuit transforms the voltage supplied from the power supply plane to generate the power supply voltage.

5. The PCB according to claim 4, wherein the voltage supplied from the power supply plane is higher than the power supply voltage.

6. The PCB according to claim 1, further comprising a signal line that supplies a control signal received from an outside of the plate-like member to the power supply circuit.

7. The PCB according to claim 6, wherein the power supply circuit turns on/off an output of the power supply voltage in response to the control signal.

8. The PCB according to claim 6, wherein the power supply circuit changes a voltage value of the power supply voltage in response to the control signal.

9. The PCB according to claim 1, wherein
the at least one power supply line comprises a plurality of power supply lines, and
the power supply circuit outputs a plurality of output voltages having different voltage values through a plurality of electric lines, respectively.

10. The PCB according to claim 9, further comprising a signal line that supplies a control signal received from an outside of the plate-like member to the power supply circuit.

11. The PCB according to claim 10, wherein the power supply circuit separately turns on/off outputs of the plurality of power supply voltages in response to the control signal.

12. The PCB according to claim 10, wherein the power supply circuit separately changes voltage values of the plurality of power supply voltages in response to the control signal.

13. The PCB according to claim 1, further comprising a ground plane that supplies the ground voltage to the power supply circuit, the ground plane being formed in the PCB.

14. The PCB according to claim 1, wherein the at least one power supply circuit comprises a plurality of power supply circuits.

15. A method of manufacturing a printed circuit board (PCB), comprising:
forming a power supply circuit that outputs a power supply voltage and a ground voltage, the power supply circuit being embedded in a plate-like member in a region in which a semiconductor device is mounted;
forming a power supply line that supplies the power supply voltage output from the power supply circuit to the semiconductor device, in the plate-like member between the semiconductor device and the power supply circuit; and
forming a ground line that supplies the ground voltage output from the power supply circuit to the semiconductor device, in the plate-like member between the semiconductor device and the power supply circuit.
